(19) United States
(12) Patent Application Publication
(10) Pub. No.: US 2023/0114303 A1
(43) Pub. Date: Apr. 13, 2023

(54) ENERGY-AWARE PROCESSING SYSTEM

(71) Applicant: Nokia Technologies Oy, Espoo (FI)

(72) Inventors: Alessandro MONTANARI, Cambridge, Cambridgeshire (GB); Mohammed ALLOULAH, Cambridge, Cambridgeshire (GB)

(21) Appl. No.: 17/904,633

(22) PCT Filed: Mar. 8, 2021
(86) PCT No.: PCT/EP2021/055814

§ 371 Date: Aug. 19, 2022

(30) Foreign Application Priority Data
Mar. 10, 2020 (GB) 2003443.5

(51) Int. Cl. H02J 3/14; H02J 3/00

(52) U.S. Cl. CPC H02J 3/144; H02J 3/004

(57) ABSTRACT

An apparatus, method and computer program is described comprising: degrading an acquired data signal, using a source coding module, to generate a degraded signal having a fidelity dependent on a first measure of available energy, wherein the acquired data signal is degraded based on a scalar dependent on said first measure of available energy; and generating an output based on the degraded data signal, wherein the output is generated using an inference module that has parameters dependent on a second measure of available energy, wherein the inference module is configured to output degradable inferences dependent on the degraded signal received by the inference module from the source coding module.

### FIELD

The present specification relates to energy-aware processing systems, such as systems comprising joint source coding and inference modules.

### BACKGROUND

The widespread of machine learning (ML) algorithms across many application domains has led to concerns over associated energy demands. Although considerable progress has been made, there remains a need for further developments, particularly in the field of energy-ware ML.

### SUMMARY

In a first aspect, this specification describes an apparatus comprising means for is performing: degrading an acquired data signal (e.g. “sparsifying” or “coarsifying” the data, as discussed in detail below), using a source coding module, to generate a degraded signal having a fidelity dependent on a first measure of available energy, wherein the acquired data signal is degraded based on a scalar dependent on said first measure of available energy; and generating an output based on the degraded data signal, wherein the output is generated using an inference module (e.g. an ML inference module) that has parameters dependent on a second measure of available energy, wherein the inference module is configured to output degradable inferences dependent on the degraded signal received by the inference module from the source coding module. In this way, the fidelity of the acquired data signal may be actively reduced when the available energy is low. Reducing the fidelity of the acquired signal can result in reduced power consumption during processing. The parameters of the inference module may be dependent on the fidelity of the source coding implemented by the source coding module.

Some example embodiments further comprise means for performing: selecting the inference module from a plurality of available inference modules dependent on the second measure of available energy. Alternatively, a single inference module may be adapted.

Some example embodiments further comprise means for performing: determining the first measure of available energy, wherein the first measure of available energy is a measure of an instantaneous energy supply.

Some example embodiments further comprise means for performing: determining the second measure of available energy, wherein the second measure of available energy is a forecast of future available energy. The energy forecast may be static over a longer term than that first measure of available energy.

In some example embodiments, the parameters of the inference module are trained together with the source coding module at a particular measure of available energy.

The inference module may have a plurality of trainable parameters.

The acquired data signal may comprise an audio data signal, wherein the scalar defines a coarseness of the degraded data signal. Alternatively, or in addition, the acquired data signal may comprise an image data signal, wherein the scalar defines a quantization level of the degraded data signal. For example, discrete cosine transform (DCT) image dimensions may be re-sized to reduce model parameter size.

In a second aspect, this specification describes an apparatus comprising means for performing: training parameters of an inference module that forms part of a system comprising a source coding module and the inference module, wherein the source coding module is configured to degrade an acquired data signal to generate a degraded data signal, based on a scalar selected dependent on an available energy, wherein the inference module is trained, for a particular available energy, together with the source coding module, such that the inference module is configured to output degradable inferences dependent on the degraded signal received by the inference module from the source coding module. In this way, the inference module may learn distortion tolerant decoder functions during training.

Some example embodiments further comprise means for performing: training a plurality of inference modules, each inference module configured to operate for a defined measure of available energy.

The inference module may have a plurality of trainable parameters.

The acquired data signal may comprise an audio data signal, wherein the scalar defines a coarseness of the degraded data signal. Alternatively, or in addition, the acquired data signal may comprise an image data signal, wherein the scalar defines a quantization level of the degraded data signal. For example, discrete cosine transform (DCT) image dimensions may be re-sized to reduce model parameter size.

The said means of the first or second aspect may comprise: at least one processor; and at least one memory including computer program code, the at least one memory and the computer program configured, with the at least one processor, to cause the performance of the apparatus.

In a third aspect, this specification describes a method comprising: degrading an acquired data signal (e.g. “sparsifying” or coarsifying” the data, as discussed in detail below), using a source coding module, to generate a degraded signal having a fidelity dependent on a first measure of available energy, wherein the acquired data signal is degraded based on a scalar dependent on said first measure of available energy; and generating an output based on the degraded data signal, wherein the output is generated using an inference module (e.g. an ML inference module) that has parameters dependent on a second measure of available energy, wherein the inference module is configured to output degradable inferences dependent on the degraded signal received by the inference module from the source coding module. The parameters of the inference module may be dependent on the fidelity of the source coding implemented by the source coding module.

Some example embodiments further comprise: selecting the inference module from a plurality of available inference modules dependent on the second measure of available energy. Alternatively, a single inference module may be adapted.

Some example embodiments further comprise: determining the first measure of available energy, wherein the first measure of available energy is a measure of an instantaneous energy supply.

Some example embodiments further comprise: determining the second measure of available energy, wherein the second measure of available energy is a forecast of future available energy. The energy forecast may be static over a longer term than that first measure of available energy.

In some example embodiments, the parameters of the inference module are trained together with the source coding module at a particular measure of available energy.

The acquired data signal may comprise an audio data signal, wherein the scalar defines a coarseness of the degraded data signal. Alternatively, or in addition, the acquired data signal may comprise an image data signal, wherein the scalar defines a quantization level of the degraded data signal.

In a fourth aspect, this specification describes a method comprising: training parameters of an inference module that forms part of a system comprising a source coding module and the inference module, wherein the source coding module is configured to degrade an acquired data signal to generate a degraded data signal, based on a scalar selected dependent on an available energy, wherein the inference module is trained, for a particular available energy, together with the source coding module, such that the inference module is configured to output degradable inferences dependent on the degraded signal received by the inference module from the source coding module. In this way, the inference module may learn distortion tolerant decoder functions during training.

Some example embodiments further comprise: training a plurality of inference modules, each inference module configured to operate for a defined measure of available energy.

The acquired data signal may comprise an audio data signal, wherein the scalar defines a coarseness of the degraded data signal. Alternatively, or in addition, the acquired data signal may comprise an image data signal, wherein the scalar defines a quantization level of the degraded data signal.

In a fifth aspect, this specification describes an apparatus configured to perform any method as described with reference to the third or fourth aspects.

In a sixth aspect, this specification describes computer-readable instructions which, when executed by computing apparatus, cause the computing apparatus to perform any method as described with reference to the third or fourth aspects.

In a seventh aspect, this specification describes a computer program comprising instructions for causing an apparatus to perform at least the following: degrading an acquired data signal, using a source coding module, to generate a degraded signal having a fidelity dependent on a first measure of available energy, wherein the acquired data signal is degraded based on a scalar dependent on said first measure of available energy; and generating an output based on the degraded data signal, wherein the output is generated using an inference module that has parameters dependent on a second measure of available energy, wherein the inference module is configured to output degradable inferences dependent on the degraded signal received by the inference module from the source coding module.

In an eighth aspect, this specification describes a computer program comprising instructions for causing an apparatus to perform at least the following: training parameters of an inference module that forms part of a system comprising a source coding module and the inference module, wherein the source coding module is configured to degrade an acquired data signal to generate a degraded data signal, based on a scalar selected dependent on an available energy, wherein the inference module is trained, for a particular available energy, together with the source coding module, such that the inference module is configured to output degradable inferences dependent on the degraded signal received by the inference module from the source coding module.

In a ninth aspect, this specification describes a computer-readable medium (such as a non-transitory computer-readable medium) comprising program instructions stored thereon for performing at least the following: degrading an acquired data signal, using a source coding module, to generate a degraded signal having a fidelity dependent on a first measure of available energy, wherein the acquired data signal is degraded based on a scalar dependent on said first measure of available energy; and generating an output based on the degraded data signal, wherein the output is generated using an inference module that has parameters dependent on a second measure of available energy, wherein the inference module is configured to output degradable inferences dependent on the degraded signal received by the inference module from the source coding module.

In a tenth aspect, this specification describes a computer-readable medium (such as a non-transitory computer-readable medium) comprising program instructions stored thereon for performing at least the following: training parameters of an inference module that forms part of a system comprising a source coding module and the inference module, wherein the source coding module is configured to degrade an acquired data signal to generate a degraded data signal, based on a scalar selected dependent on an available energy, wherein the inference module is trained, for a particular available energy, together with the source coding module, such that the inference module is configured to output degradable inferences dependent on the degraded signal received by the inference module from the source coding module.

In an eleventh aspect, this specification describes an apparatus comprising: at least one processor; and at least one memory including computer program code which, when executed by the at least one processor, causes the apparatus to: degrade an acquired data signal, using a source coding module, to generate a degraded signal having a fidelity dependent on a first measure of available energy, wherein the acquired data signal is degraded based on a scalar dependent on said first measure of available energy; and generate an output based on the degraded data signal, wherein the output is generated using an inference module that has parameters dependent on a second measure of available energy, wherein the inference module is configured to output degradable inferences dependent on the degraded signal received by the inference module from the source coding module.

In a twelfth aspect, this specification describes an apparatus comprising: at least one processor; and at least one memory including computer program code which, when executed by the at least one processor, causes the apparatus to: train parameters of an inference module that forms part of a system comprising a source coding module and the inference module, wherein the source coding module is configured to degrade an acquired data signal to generate a degraded data signal, based on a scalar selected dependent on an available energy, wherein the inference module is trained, for a particular available energy, together with the source coding module, such that the inference module is configured to output degradable inferences dependent on the degraded signal received by the inference module from the source coding module.

In a thirteenth aspect, this specification describes an apparatus comprising: means (such as a source coding module) for degrading an acquired data signal to generate a degraded signal having a fidelity dependent on a first measure of available energy, wherein the acquired data signal is degraded based on a scalar dependent on said first measure of available energy; and means (such as an inference module) for generating an output based on the degraded data signal, wherein the means for generating the output has parameters dependent on a second measure of available energy and is configured to output degradable inferences dependent on the degraded signal received from the source coding module.

In a fourteenth aspect, this specification describes an apparatus comprising: means (such as a training module) for training parameters of an inference module that forms part of a system comprising a source coding module and the inference module, wherein the source coding module is configured to degrade an acquired data signal to generate a degraded data signal, based on a scalar selected dependent on an available energy, wherein the inference module is trained, for a particular available energy, together with the source coding module, such that the inference module is configured to output degradable inferences dependent on the degraded signal received by the inference module from the source coding module.

### BRIEF DESCRIPTION OF THE DRAWINGS

Example embodiments will now be described, by way of example only, with reference to the following schematic drawings, in which:

FIG. 1 is a block diagram of a system in accordance with an example embodiment;

FIG. 2 is a flow chart showing an algorithm in accordance with an example embodiment;

FIG. 3 is a block diagram of a system in accordance with an example embodiment;

FIG. 4 is a block diagram of a system in accordance with an example embodiment;

FIG. 5 is a plot showing outputs in accordance with an example embodiment;

FIG. 6 is a plot showing outputs in accordance with an example embodiment;

FIG. 7 is a flow chart showing an algorithm in accordance with an example embodiment;

FIG. 8 is a flow chart showing an algorithm in accordance with an example embodiment;

FIG. 9 is a plot showing performance metrics of example embodiments;

FIG. 10 is a plot showing performance metrics of example embodiments;

FIG. 11 is a flow chart showing an algorithm in accordance with an example embodiment;

FIG. 12 is a block diagram of a system in accordance with an example embodiment;

FIG. 13 is a plot showing performance metrics of example embodiments;

FIG. 14 is a block diagram of a neural network in accordance with an example embodiment;

FIGS. 15 and 16 are plots showing outputs in accordance with example embodiments;

FIG. 17 is a table of data in accordance with an example embodiment;

FIG. 18 is a block diagram of components of a system in accordance with an example embodiment; and

FIGS. 19A and 19B show tangible media, respectively a removable non-volatile memory unit and a Compact Disc (CD) storing computer-readable code which when run by a computer perform operations according to example embodiments.

### DETAILED DESCRIPTION

The scope of protection sought for various embodiments of the invention is set out by the independent claims. The embodiments and features, if any, described in the specification that do not fall under the scope of the independent claims are to be interpreted as examples useful for understanding various embodiments of the invention.

In the description and drawings, like reference numerals refer to like elements throughout.

As noted above, the widespread of machine learning (ML) algorithms (or similar algorithms) across many application domains, has led to concerns over associated energy demands. By way of example, three application domains that are particularly hard to service using current ML techniques are as follows:
Low-end applications that run on ultra-low power devices which rely on harvested ambient energy. Real-world examples include wildlife monitoring and cognitive augmentation, which are characterised by a high uncertainty in power availability. The times at which such devices are awake and can sense the environment or process incoming data may be unpredictable. Under these conditions, energy supply may fluctuate significantly. The net effect can be an uptime of few milliseconds only, with periods of power denial that could span hours.
Applications on consumer devices. ML workloads are increasingly common in consumer devices like smartphones and wearables. However, battery capacity remains a significant limitation, especially given shrinking form factors and the availability of inexpensive computation (e.g. neural accelerators embedded in modern processors).
High-end applications with significant impact on greenhouse emissions and energy supplies. Real-world examples include a smart grid peak curtailment mechanism whereby data centres are incentivised to compromise inference fidelity in favour of energy efficiency. If acted upon by data centres, large amounts of energy and greenhouse emissions can be potentially conserved.

Many state-of-the-art ML and similar models lack scalability. That is, ML models may require invasive retraining and/or architectural restructuring when their resource-performance operating point is to be adjusted. Although the severity of the required re-engineering varies, such processes may be untenable for the purpose of dynamic energy-aware performance adaptation. That is, many of these techniques are at heart static and unable to cater for widely fluctuating resource availability.

Furthermore, many ML and similar models exhibit an all-or-nothing behaviour at the designated resource-performance point. Thus, once retrained and/or restructured, such models may only output an inference if resource availability is above a requisite threshold. Such rigidity can be problematic for application domains in which harvested energy is wasted for all but those energy levels rising above a critical operational threshold. As such, when available energy falls below this threshold, sensor nodes are unable to convert data into inferences. In certain time-sensitive applications, this all-or-nothing behaviour may further result in data becoming stale owing to sensor nodes' inability to act on data in a timely fashion.

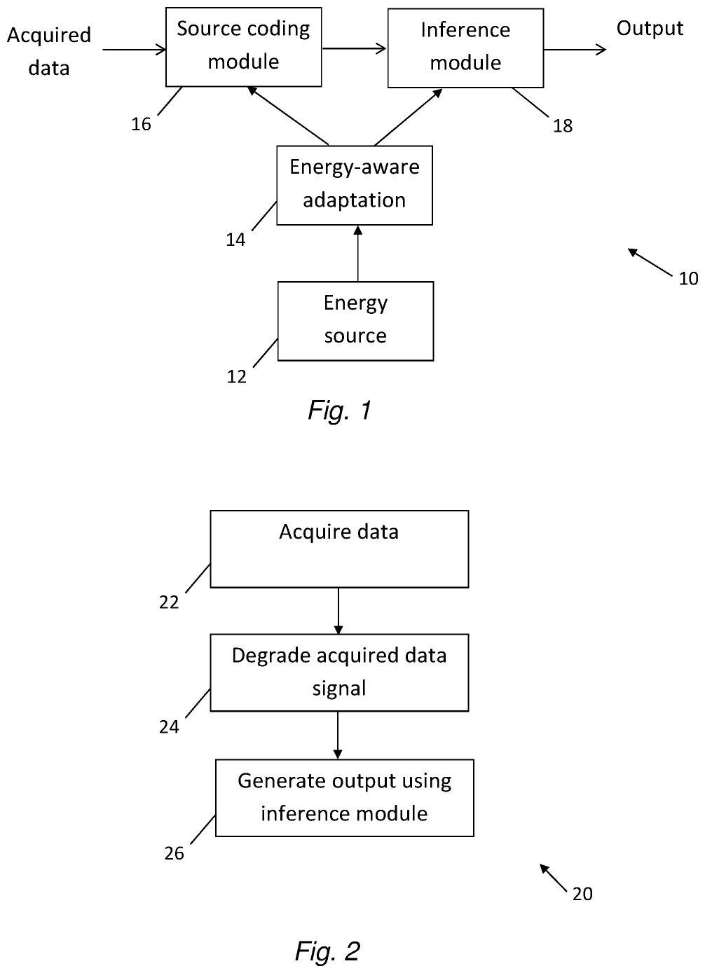

FIG. 1 is a block diagram of a system, indicated generally by the reference numeral 10, in accordance with an example embodiment.

The system 10 comprises an energy source 12, an energy-aware adaptation module 14, a source coding module 16 and an inference module 18. The energy source 12 is a variable energy source, which dictates the instantaneous energy budget for computational workloads.

The energy-aware adaptation module 14 is a logic module that seeks to adapt computations to available energy. Energy-aware adaptations controlled by the module 14 include controlling the functionality or performance of the source coding module 16 and the inference module 18. As discussed further below, the inference module may be implemented using a neural network (e.g. a deep neural networks (DNN)) which can tolerate inputs of reduced quality, while still being able to produce inferences whose accuracies are dependent on (e.g. proportional to) instantaneous energy levels. The combined operation is made possible by designing and/or training the source coding module 16 and the inference module 18 together.

In general terms, the inference module 18 provides for degradable inference, namely inference whose quality varies in proportion to the instantaneous energy supplied. As discussed below, the system 10 supports two common modalities in recognition tasks: vision and audio (and may, of course, be used for other tasks). In contrast to static model engineering techniques, energy-aware source encoding seeks to achieve smooth inference degradability over a wide-range of energy availability levels through the use of a single control parameter at the encoder which, in turn, also controls the configurations of the inference module.

FIG. 2 is a flow chart showing an algorithm, indicated generally by the reference numeral 20, in accordance with an example embodiment. The algorithm 20 may be implemented using the system 10 described above.

The algorithm 20 starts at operation 22, where data is acquired. The data may be audio data (acquired, for example, using a microphone) or visual data (acquired, for example, using a camera system), but the principles described herein are applicable to many data sources. The acquired data may be provided to the source coding module 16 of the system 10.

At operation 24, the acquired data signal is degraded, for example using the source coding module 16. As discussed below, degrading the acquired data signal may involve techniques such as “sparsifying” or “coarsifying” the data based on the available energy, such that the fidelity of the acquired data signal may be actively reduced when the available energy is low. The source coding module may generate a degraded signal having a fidelity dependent on a first measure of available energy, wherein the acquired data signal is degraded based on a scalar dependent on said first measure of available energy. Providing data having a lower fidelity (e.g. fewer data points) may result in reduced power consumption during processing (e.g. during processing by the inference module 18 and/or the source coding module 16).

At operation 26, an output is generated based on the degraded data signal, wherein the output is generated using an inference module (e.g. the inference module 18) that has parameters dependent on the fidelity of the energy-aware source encoding. The inference module may be configured to output degradable inferences based on (e.g. proportional to) the degraded signal received by the inference module from the source coding module.

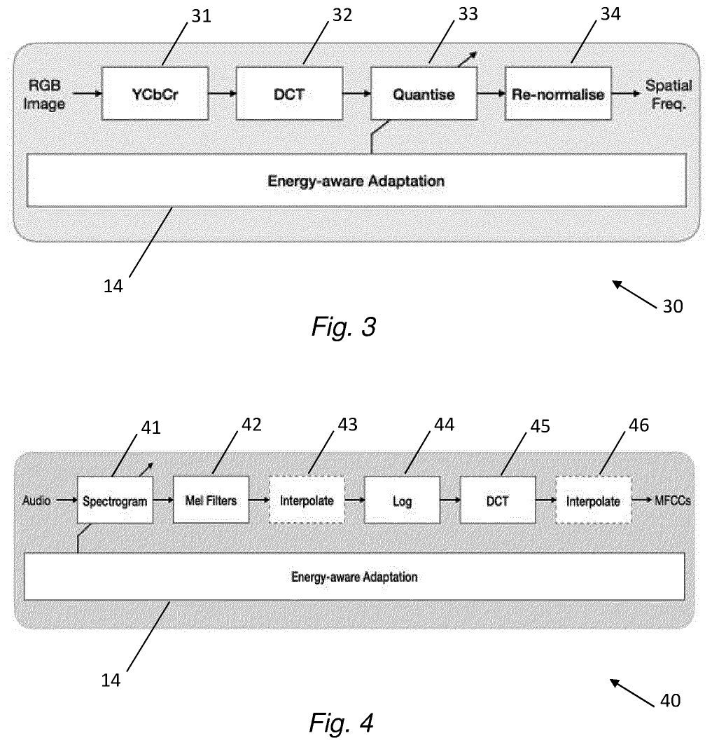

FIG. 3 is a block diagram of a system, indicated generally by the reference numeral 30, in accordance with an example embodiment. The system 30 may be used to process vision data (e.g. JPEG data) in accordance with the principles described herein (as noted above, the system 10, and the algorithm 20, may be used to process vision data).

The system 30 includes the energy-aware adaptation module 14 of the system 10 described above and further comprises a plurality of modules 31 to 34 that are an example implementation of the source coding module 16 described above.

The modules 31 to 34 comprise a YCbCr module 31, a DCT module 32, a variable quantisation module 33 and a re-normalisation module 34.

The system 30 may receive RGB data as “acquired data”, which data is converted to YCbCr data by the module 31. In the system 30, the DCT module 32 generate a discrete cosine transform (DCT) based on the YCbCr data. The DCT data is quantised by the quantisation module 33 and normalised by the re-normalisation module 34.

The quantisation module 33 is variable (as indicated by the diagonal arrow in FIG. 3). Specifically, the quantization module is variable such that it can be adapted based on instantaneous energy levels. By way of example, the JPEG standard defines quantisation as:

$${S}_{c h}^{q} = round ( q \frac{{S}_{c h}}{{Q}_{c h}} ) \qquad Eq ( 1 )$$

where:
S_{ch} is a discrete consine transform (DCT) subblock of channel ch ∈[Y, Cb, Cr]
Q_{ch} is the quantisation table for that channel.
q is a quality scaler that controls the extent of sparsification
S^{q} is the resultant quantised subblock.

We observe that q scales the dynamic range of the DCT coefficients. Thus, the renormalisation module 34 is used to re-normalise the input to the DNN according to:

$${S}_{c h}^{q} = {q}^{- 1} round ( q \frac{{S}_{c h}}{{Q}_{c h}} ) \qquad Eq ( 2 )$$

or any equivalent mathematical operation that harmonises the numerical dynamic range of different quantisation levels.

Thus, the acquired data that provides the input to the source coding module 16 described above may comprise an image data signal, wherein a scalar (q) defines a quantization level of the degraded data signal output by the source coding module 16.

FIG. 4 is a block diagram of a system, indicated generally by the reference numeral 40, in accordance with an example embodiment. The system 40 may be used to process audio data in accordance with the principles described herein.

The system 40 includes the energy-aware adaptation module 14 of the system 10 described above and further comprises a plurality of modules 41 to 46 that are an example implementation of the source coding module 16 described above.

The modules 41 to 46 comprise a variable spectrogram module 41, a Mel filters module 42, an optional first interpolation module 43, a log module 44, a DCT module 45 and a second optional interpolation module 46.

The system 40 may receive audio data as “acquired data” and may output mel-frequency cepstral coefficients (MFCCs) or log mel-frequency spectral coefficients (MFSCs).

The spectrogram module 41 is variable (as indicated by the diagonal arrow in FIG. 4), based on instantaneous energy levels.

The source coding module 16 may be used to degrade audio MFCCs by reducing their temporal granularity i.e. by making transitions in their spectra over time coarser. Concretely, recalling that the continuous-time spectrogram of signal x(t) is given by:

spectrogram{x}(τ,w)=|∫_{-∞}^{∞}x(t)w(t−τ)e^{-jwt}dt|² Eq (3)

Specifically, the source coding module 16 may be use a larger stride τ to “coarsify” the resultant spectrogram. That is, compared to the sparsification in the vision encoder, this audio “coarsification” trades-off fine-grained temporal transitions in the spectrogram for significant computational gains. However, once trained, the distortion-tolerant inference module 18 may require fixed MFCC temporal granularity as input. Therefore, the source coding module 16 may linearly interpolate the coarse-grained spectrogram onto the original fine spectral grid in order to equalise for the expected inference module input (e.g. using the optional second interpolator 46 described above).

Thus the acquired data that provides the input to the source coding module 16 described above may comprise an audio data signal, wherein a scalar defines a coarseness of the degraded data signal output by the source coding module 16.

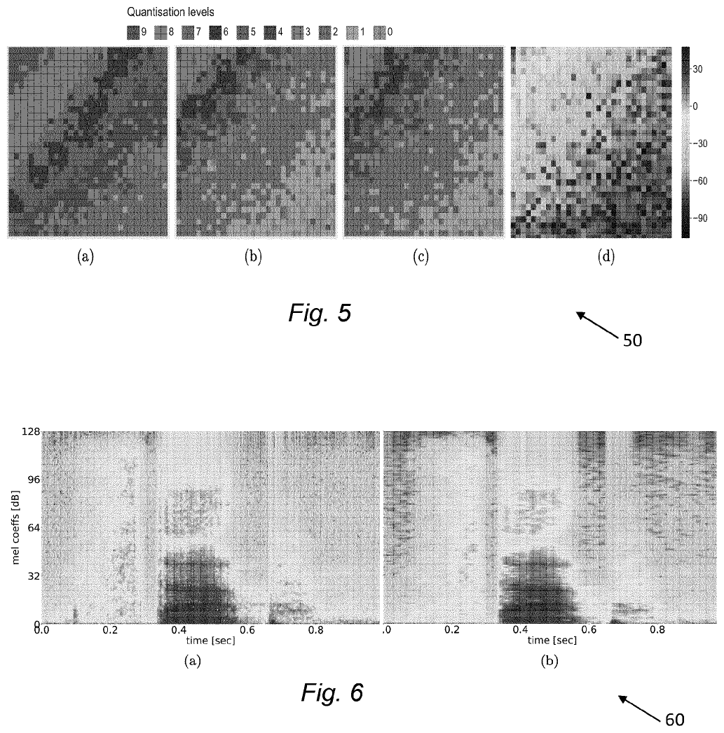

FIG. 5 is a plot, indicated generally by the reference numeral 50, showing outputs in accordance with an example embodiment.

The plot 50 is a visualisation for 10 levels of JPEG-style DCT quantisation averaged across the CIFAR10 dataset for the three YCbCr colour space channels: (a) Y, (b) Cb, and (c) Cr. Increasing the quality scaler results in a progressive retention of more spatial frequencies. (d) CIFAR10 average spatial frequency decay (dB); dynamic range is in excess of 120 dB.

In the plot 50, 10 quantisation levels were swept in order to progressively sparsify the DCT representation of tiny 32×32 images. These sparsified DCT images were then averaged channel-wise in the YCbCr colour space. Beginning with the Y channel shown in the plot (a), the loth level aggressively compresses the image into a small blue cluster around the DC value at the upper left corner. As we relax compression—using q in Equation (2)—more DCT coefficients emanate outwards from DC until all spatial frequencies are retained beginning at the 3rd quantisation level shown in grey. Comparatively the chroma channels are quantised further as per the JPEG standard. This is reflected in the average coefficients retained across quantisation levels for the Cb and Cr channels of the plots b and c respectively.

FIG. 6 is a plot, indicated generally by the reference numeral 60, showing outputs in accordance with an example embodiment. The plot 60 is a snapshot illustration of degradable audio encoding: (a) original fine-grained spectrogram of ems stride, and (b) coarse-grained spectrogram of 16 ms stride equalised to the same original length via linear interpolation.

As discussed above, the system 10 comprises an inference module 18. The inference module receives degradable encoded outputs from the source coding module 16.

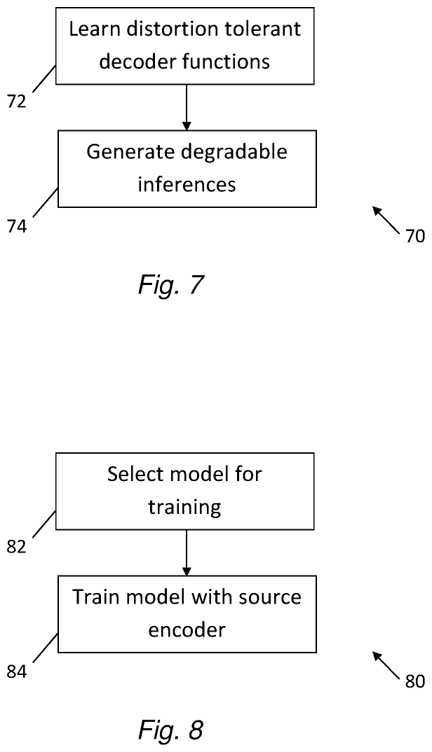

FIG. 7 is a flow chart showing an algorithm, indicated generally by the reference numeral 70, in accordance with an example embodiment.

The algorithm 70 starts at operation 72, where an inference module (such as the inference module 18) learns distortion tolerant decoder functions. The learning referred to in operation 72 is carried out during training of the inference module.

At operation 74 of the algorithm, the inference module outputs degradable inferences based on the degradable input received from the source encoder.

For example, for both the audio and vision examples discussed above, the relevant inference module (e.g. a suitably trained neural network) takes degradable domain-expert encodings (e.g. quantised JPEG data or coarsified audio data) as input and generates inferences based on the received inputs based on the training of the inference module.

The training of the inference module 18 may take many forms.

Consider the example of vision data (such as JPEG data). A data augmentation approach may be taken. Examining the plot 50 described above with reference to FIG. 5 suggests that spatial frequencies naturally cluster around DC, occupying more of the 2D spectral grid as we increase the quality scaler q (see Equation (2) described above). Further, energy decays rapidly at higher spatial frequencies as shown in the CIFAR dataset average, see plot (d)—in which the dynamic range is in excess of 120 dB. Thus, we would expect diminishing contributions to DNN activations from such higher spatial frequencies. It is, therefore, viable to train a DNN on a high quality scaler (e.g. q_{HI}=100) and expect it to still retain good performance at inputs of marginally reduced quality (e.g. q=90).

In one example implementation, state-of-the-art image augmentation was carried out in the RGB domain. That is, during training, standard augmentation techniques, such as rotation and blur, may be utilised, with the augmented data then transformed into new RGB images to our spatial frequency representation. We have found this approach to be effective at reaching DCT networks of accuracies on par with their RGB counterparts.

Similar to vision, an inference module for audio applications may employ standard audio data augmentation techniques, such as background noise addition and time shifting. Both may be used in order to ensure the model generalises to real-world scenarios with expected variabilities in ambient noise (e.g. factory, retail, or home settings) and/or trigger instance (e.g. up to ±100 ms).

For both vision and audio applications, an ensemble of models may be trained with different source encoder fidelities i.e. q for vision and τ for audio as per Equations (2) and (3) respectively. As discussed further below, in some example implementations, three levels of inference module distortion-tolerance may be considered: high (HI), middle (MID), and low (LO), for both vision and audio i.e. q_{HI}, q_{MID}, q_{LO}, and τ_{HI}, τ_{MID}, and τ_{LO}, respectively.

In another example implementation, a plurality of q scalers may be used to generate images augmentations at different qualities in order to simultaneously enhance the DNN accuracy and tolerance to increased DCT coefficient de-activation (e.g. at q_{HI}=100, q_{MID}=60, and q_{LO}=30).

FIG. 8 is a flow chart showing an algorithm, indicated generally by the reference numeral 80, in accordance with an example embodiment.

The algorithm 80 starts at operation 82 where one of a plurality of models (e.g. HI inference modules) is selected for training. Next, at operation 84, the model is trained.

In the operation 84, the selected model is trained together with the relevant source encoding. Thus, the selected model is trained for use with a source encoder providing a particular level of degradation of an acquired data input. Specifically, the source coding module may be configured to degrade an acquired data signal based on a selected scalar.

As discussed further below, the parameters of the inference module may be trained together with the source coding module at a particular measure of available energy (e.g. based on a scalar selected dependent on an available energy).

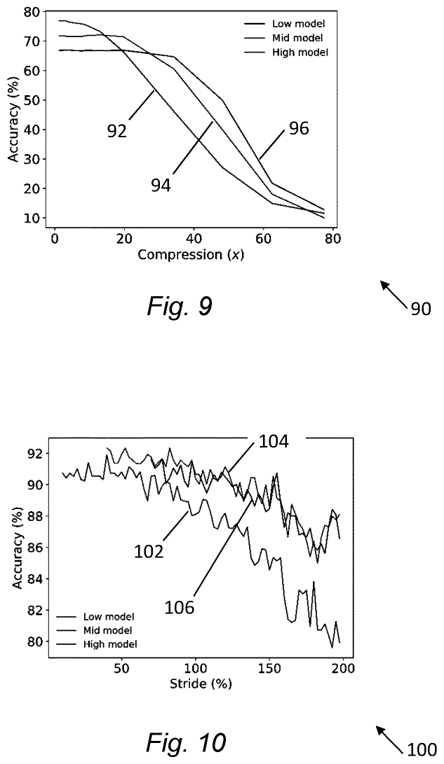

FIG. 9 is a plot, indicated generally by the reference numeral 90, showing performance metrics of example embodiments. The plot 90 is based on the processing of vision data and shows accuracy variation for different compression levels for three vision model configurations. Compression was achieved by reducing the quality scalar of the vision encoder, resulting in a sparser input representation.

FIG. 9 shows three plots: a first plot 92 based on an inference module trained for a relatively high fidelity configuration, a second plot 94 based on an inference module trained for a moderate fidelity configuration and a third plot 96 for an inference module trained for a relatively low fidelity configuration.

Inspecting FIG. 9 reveals how the model trained with the high fidelity configuration (i.e. q_{HI}) achieves top accuracy (77%), followed by the MID and LO configurations (72% and 65% respectively). This is because in HI configuration, a large portion of the DCT coefficients are preserved and available for use by the model as discriminative features on target classes. In terms of response to the input compression, all three models show a graceful degradation in accuracy as the compression rate increases. At a closer inspection, we observe that training with larger quality scalers (from LO to HI) causes steeper accuracy drops with increased compression. Conversely, models trained with smaller quality scalers tend to preserve accuracy at higher compression levels—e.g., accuracy drop for the LO model is marginal up to approximately 38× compression, while MID and HI models tend to lose accuracy more rapidly at lower compression rates. Such behaviour can be understood by considering model training. Specifically, training with a smaller quality scaler forces the model to learn to classify input data using fewer quantised coefficients, hence becoming less sensitive to compression compared to models trained with higher quality scalers. As described further below, we can take advantage of this effect by selecting the most appropriate available model based on the fidelity of an energy-aware source coding.

FIG. 10 is a plot, indicated generally by the reference numeral 100, showing performance metrics of example embodiments. The plot wo was based on the processing of audio data having different window strides for three audio model configurations. The stride is increased from the value used to train the model up to double the window length. The curves have different lengths because each model has been trained with a different window stride. The coarse-grained spectrogram has been interpolated in the MFCC domain.

FIG. 10 depicts graceful accuracy degradation for the three audio models trained on progressively increasing spectrogram strides. Specifically, a first plot 102 based on an relatively high (HI) fidelity configuration, a second plot 104 is based on a moderate (MID) fidelity configuration and a third plot 106 is based on relatively low (LO) fidelity configuration. For each model, the testing audio spectrogram stride is varied from the training value to double the spectrogram window length i.e. τ^{test}∈[τₓ, 2W], where W is the spectrogram window length and X∈[LO,MID,HI]. We note the following. First, the accuracy drop is marginal (around 10% at worst) compared to the vision models discussed above, even when the stride is longer than the window size. This means that a certain amount of input data can be skipped, thereby substantially reducing the computational workload while simultaneously maintaining good accuracy. Second, similar to vision, the model trained with the HI setting is more sensitive to compression and tends to lose accuracy quicker than MID and LO models. However, in this instance, the HI model is ˜1% off from top accuracy, achieved by the MID configuration. Third, the audio models display noisier accuracy degradations as their strides are varied—compared to much smoother accuracy degradations in vision models.

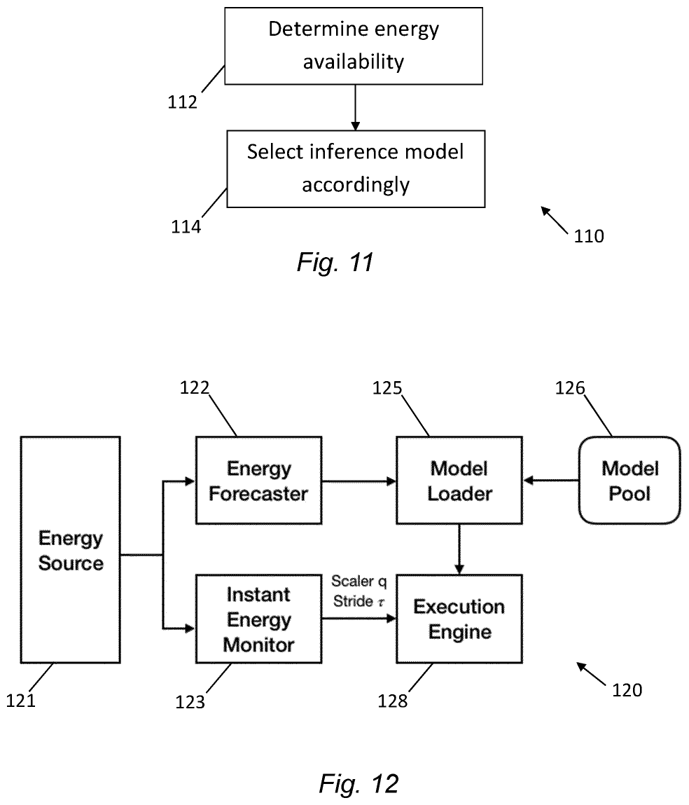

FIG. 11 is a flow chart showing an algorithm, indicated generally by the reference numeral 110, in accordance with an example embodiment.

The algorithm no starts at operation 112, where energy availability is determined.

Next, at operation 114, an inference module is selected from a plurality of available inference modules dependent on energy availability determined in operation 112. It should be noted that in an alternative embodiment, an inference module may be adapted based on energy availability (rather than selecting one of a plurality of modules). Thus, for example, a single inference module may be provided that is itself adaptable.

As discussed further below, the operation 112 may be implemented by determining a measure of an instantaneous energy supply and/or by generating a forecast of future is available energy.

FIG. 12 is a block diagram of a system, indicated generally by the reference numeral 120, in accordance with an example embodiment.

The system 120 comprises an energy source 121, an energy forecaster module 122, an instant energy monitor 123, a model loader 125, a model pool 126 and an execution engine 128.

As discussed further below, the energy source 121 is an example of the energy source 12 described above, the energy forecaster 122 and the instant energy monitor 123 may collectively implement the energy-aware adaptation module 14 and the execution engine 128 may include the source coding module 16 and the inference module 18 of the system 10.

In the use of the system 120, the energy forecaster module 122 monitors the available energy on a relatively long-term scale and predicts how variable the available energy would be in the future. The energy forecaster module 122 then provides energy forecast information to the model loader 125 for the selection of the appropriate inference module/inference module parameters.

The instant energy monitor 123 tracks energy fluctuations of the energy source 121 with fine granularity and selects the appropriate parameters for the source coding module (e.g. the appropriate scaler (for vision) or stride (for audio)). Thus, the source coding module can be configured to adapt its computational requirements to an instantaneous energy availability.

The model loader 125 determines which of a plurality of models to use (e.g. one of the LO, MID or HI models discussed above). The models are stored in the model pool 126. (Of course, the model pool 126 could include more or fewer than the three models described herein.) For example, if the energy forecaster predicts the energy to fluctuate quickly, the LO model may be preferable since it incurs a smaller accuracy loss at high compression rates, allowing the system to cope with highly variable energy levels without degrading the accuracy excessively. Otherwise, if the energy is stable, there is less need to adapt the computation frequently, the HI model may be selected to achieve is an overall higher accuracy.

Once a model has been loaded into the execution engine 128 and the instant energy monitor 123 has provided parameters for the source coding module, the execution engine can be used to process acquired data in order to generate an inference output (as discussed above with reference to the system 10).

The combination of dynamic model loading and variable input encoding allows the system to adapt gracefully to widely fluctuating and unknown energy operational conditions. The dynamic model loading functionality (based on the output of the energy forecaster module 122) enables macro adaptations that respond to different classes of energy availability patterns while the variable encoding (based on the output of the instant energy monitor 123) accounts for fine-grained and instantaneous fluctuations.

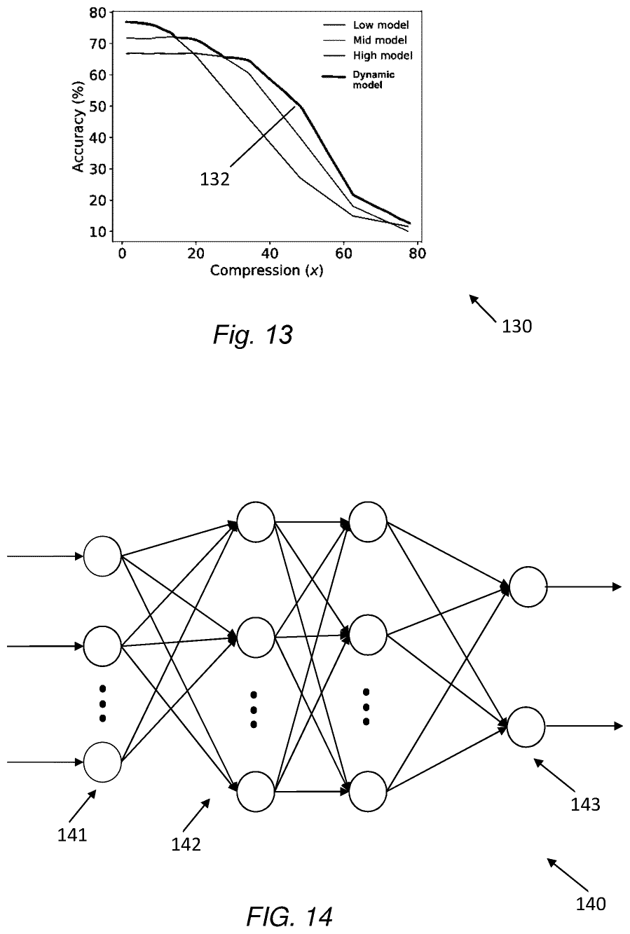

FIG. 13 is a plot, indicated generally by the reference numeral 130, showing performance metrics of example embodiments. The plot 130 shows the data of the plot 90 described above and additionally plots performance of a dynamic model 132 that seeks to provide the optimal dynamic operation at all compression rates.

In an example embodiment, the inference module may be a model (such as a machine learning model) having a plurality of trainable parameters. By way of example, FIG. 14 shows a neural network, indicated generally by the reference numeral 140, used in some example embodiments. The neural network 140 includes a first layer 141, one or more hidden layers 142 and an output layer 143.

The input layer 141 may receive one or more inputs from the source coding module 16. The output layer 143 may provide one or more outputs of the inference module.

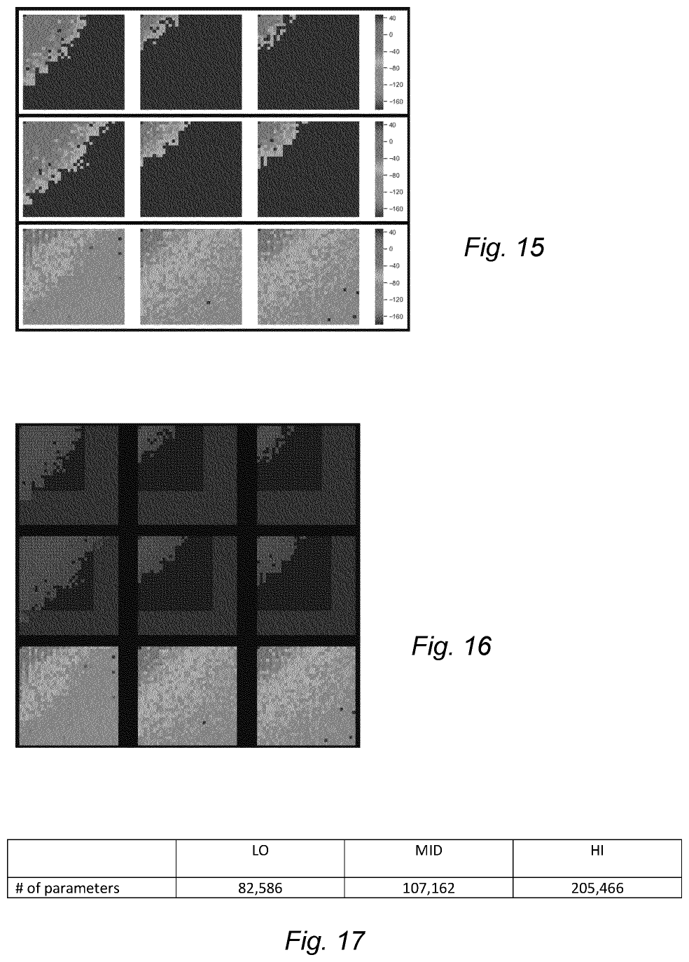

A primary motivation behind using DCT image representation for learning is to capitalise on DCT's energy clustering property. For LO, MID, and HI models (i.e. the three studied quantisation levels), FIG. 15 illustrates this clustering behaviour for the three JPEG-style channels Y, Cb, and Cr (row-wise). We observe that we can crop the LO and MID models in order to reduce the image learning representation dimensions fed to the neural network as illustrated in FIG. 16. The cropping dimensions are a design choice. For instance, we can conduct statistical characterisation in order to determine safe cropping dimensions i.e. cropping that does not cause a loss of accuracy w.r.t. the original uncropped model. For example, we found for small 32×32 images aimed at ultra-low power devices, we can safely crop LO and MID models to 12×12 and 18×18 DCT images, respectively. We then proceed to train LO and MID models for these new cropped learning representations. FIG. 17 shows the corresponding reduction in DNN parameters which amounted to around 48% for MID and 60% for LO. As such, DNN compute and energy consumption are reduced accordingly.

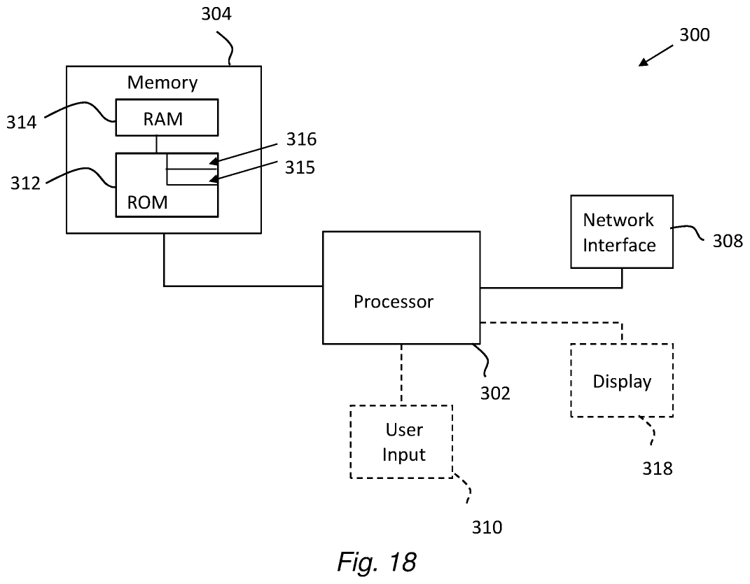

For completeness, FIG. 18 is a schematic diagram of components of one or more of the example embodiments described previously, which hereafter are referred to generically as a processing system 300. The processing system 300 may, for example, be the apparatus referred to in the claims below.

The processing system 300 may have a processor 302, a memory 304 closely coupled to the processor and comprised of a RAM 314 and a ROM 312, and, optionally, a user input 310 and a display 318. The processing system 300 may comprise one or more network/apparatus interfaces 308 for connection to a network/apparatus, e.g. a modem which may be wired or wireless. The network/apparatus interface 308 may also operate as a connection to other apparatus such as device/apparatus which is not network side apparatus. Thus, direct connection between devices/apparatus without network participation is possible.

The processor 302 is connected to each of the other components in order to control operation thereof.

The memory 304 may comprise a non-volatile memory, such as a hard disk drive (HDD) or a solid state drive (SSD). The ROM 312 of the memory 304 stores, amongst other things, an operating system 315 and may store software applications 316. The RAM 314 of the memory 304 is used by the processor 302 for the temporary storage of data. The operating system 315 may contain code which, when executed by the processor implements aspects of the algorithms 20, 70, 80 and no described above. Note that in the case of small device/apparatus the memory can be most suitable for small size usage i.e. not always a hard disk drive (HDD) or a solid state drive (SSD) is used.

The processor 302 may take any suitable form. For instance, it may be a microcontroller, a plurality of microcontrollers, a processor, or a plurality of processors.

The processing system 300 may be a standalone computer, a server, a console, or a network thereof. The processing system 300 and needed structural parts may be all inside device/apparatus such as IoT device/apparatus i.e. embedded to very small size.

In some example embodiments, the processing system 300 may also be associated with external software applications. These may be applications stored on a remote server device/apparatus and may run partly or exclusively on the remote server device/apparatus. These applications may be termed cloud-hosted applications. The processing system 300 may be in communication with the remote server device/apparatus in order to utilize the software application stored there.

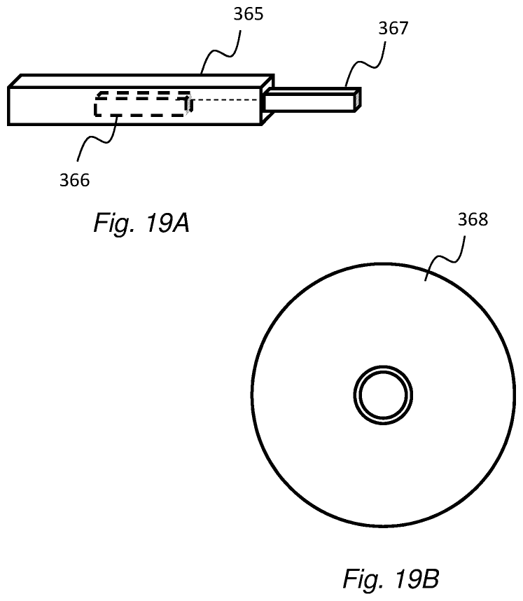

FIGS. 19A and 19B show tangible media, respectively a removable memory unit 365 and a compact disc (CD) 368, storing computer-readable code which when run by a computer may perform methods according to example embodiments described above. The removable memory unit 365 may be a memory stick, e.g. a USB memory stick, having internal memory 366 storing the computer-readable code. The internal memory 366 may be accessed by a computer system via a connector 367. The CD 368 may be a CD-ROM or a DVD or similar. Other forms of tangible storage media may be used.

Tangible media can be any device/apparatus capable of storing data/information which data/information can be exchanged between devices/apparatus/network.

Embodiments of the present invention may be implemented in software, hardware, application logic or a combination of software, hardware and application logic. The software, application logic and/or hardware may reside on memory, or any computer media. In an example embodiment, the application logic, software or an instruction set is maintained on any one of various conventional computer-readable media. In the context of this document, a “memory” or “computer-readable medium” may be any non-transitory media or means that can contain, store, communicate, propagate or transport the instructions for use by or in connection with an instruction execution system, apparatus, or device, such as a computer.

Reference to, where relevant, “computer-readable medium”, “computer program product”, “tangibly embodied computer program” etc., or a “processor” or “processing circuitry” etc. should be understood to encompass not only computers having differing architectures such as single/multi-processor architectures and sequencers/parallel architectures, but also specialised circuits such as field programmable gate arrays FPGA, application specify circuits ASIC, signal processing devices/apparatus and other devices/apparatus. References to computer program, instructions, code etc. should be understood to express software for a programmable processor firmware such as the programmable content of a hardware device/apparatus as instructions for a processor or configured or configuration settings for a fixed function device/apparatus, gate array, programmable logic device/apparatus, etc.

If desired, the different functions discussed herein may be performed in a different order and/or concurrently with each other. Furthermore, if desired, one or more of the above-described functions may be optional or may be combined. Similarly, it will also be appreciated that the flow diagrams of FIGS. 2, 7, 8 and 11 are examples only and that various operations depicted therein may be omitted, reordered and/or combined.

It will be appreciated that the above described example embodiments are purely illustrative and are not limiting on the scope of the invention. Other variations and modifications will be apparent to persons skilled in the art upon reading the present specification.

Moreover, the disclosure of the present application should be understood to include any novel features or any novel combination of features either explicitly or implicitly disclosed herein or any generalization thereof and during the prosecution of the present application or of any application derived therefrom, new claims may be formulated to cover any such features and/or combination of such features.

Although various aspects of the invention are set out in the independent claims, other aspects of the invention comprise other combinations of features from the described example embodiments and/or the dependent claims with the features of the independent claims, and not solely the combinations explicitly set out in the claims.

It is also noted herein that while the above describes various examples, these descriptions should not be viewed in a limiting sense. Rather, there are several variations and modifications which may be made without departing from the scope of is the present invention as defined in the appended claims.

1-15. (canceled)

16. An apparatus comprising:
at least one processor; and
at least one memory
storing instructions that, when executed by the at least one processor, cause the apparatus at least to;
degrade an acquired data signal, using a source coding module, to generate a degraded signal having a fidelity dependent on a first measure of available energy, wherein the acquired data signal is degraded based on a scalar dependent on said first measure of available energy; and
generate an output based on the degraded data signal, wherein the output is generated using an inference module that has parameters dependent on a second measure of available energy, wherein the inference module is configured to output degradable inferences dependent on the degraded signal received by the inference module from the source coding module.

17. An apparatus as claimed in claim 16, wherein the instructions that, when executed by the at least one processor further cause the apparatus at least to:
select the inference module from a plurality of available inference modules dependent on the second measure of available energy.

18. An apparatus as claimed in claim 16, wherein the instructions that, when executed by the at least one processor further cause the apparatus at least to:
determine the first measure of available energy, wherein the first measure of available energy is a measure of an instantaneous energy supply.

19. An apparatus as claimed in claim 16, wherein the instructions that, when executed by the at least one processor further cause the apparatus at least to:
determine the second measure of available energy, wherein the second measure of available energy is a forecast of future available energy.

20. An apparatus as claimed in claim 16, wherein the parameters of the inference module are trained together with the source coding module at a particular measure of available energy.

21. An apparatus comprising:
at least one processor; and
at least one memory
storing instructions that, when executed by the at least one processor, cause the apparatus at least to;
train parameters of an inference module that forms part of a system comprising a source coding module and the inference module, wherein the source coding module is configured to degrade an acquired data signal to generate a degraded data signal, based on a scalar selected dependent on an available energy: and
train the inference module, for a particular available energy, together with the source coding module, such that the inference module is configured to output degradable inferences dependent on the degraded signal received by the inference module from the source coding module.

22. An apparatus as claimed in claim 21, wherein the instructions that, when executed by the at least one processor further cause the apparatus at least to:
train a plurality of inference modules, each inference module configured to operate for a defined measure of available energy.

23. An apparatus as claimed in claim 21, wherein the inference module has a plurality of trainable parameters.

24. An apparatus as claimed in claim 21, wherein the acquired data signal comprises an audio data signal and wherein the scalar defines a coarseness of the degraded data signal.

25. An apparatus as claimed in claim 21, wherein the acquired data signal comprises an image data signal and wherein the scalar defines a quantization level of the degraded data signal.

26. A method comprising:
degrading an acquired data signal, using a source coding module, to generate a degraded signal having a fidelity dependent on a first measure of available energy, wherein the acquired data signal is degraded based on a scalar dependent on said first measure of available energy; and
generating an output based on the degraded data signal, wherein the output is generated using an inference module that has parameters dependent on a second measure of available energy, wherein the inference module is configured to output degradable inferences dependent on the degraded signal received by the inference module from the source coding module.

27. A method as claimed in claim 26, further comprising:
determining the first measure of available energy, wherein the first measure of available energy is a measure of an instantaneous energy supply.

28. A method as claimed in claim 26, further comprising:
determining the first measure of available energy, wherein the first measure of available energy is a measure of an instantaneous energy supply.

29. A method as claimed in claim 26, further comprising:
determine the second measure of available energy, wherein the second measure of available energy is a forecast of future available energy

30. A method comprising:
training parameters of an inference module that forms part of a system comprising a source coding module and the inference module, wherein the source coding module is configured to degrade an acquired data signal to generate a degraded data signal, based on a scalar selected dependent on an available energy; and
training the inference module, for a particular available energy, together with the source coding module, such that the inference module is configured to output degradable inferences dependent on the degraded signal received by the inference module from the source coding module.

31. A method as claimed in claim 30, wherein the particular inference module is configured to operate for a defined measure of available energy.

32. A method as claimed in claim 30, wherein the acquired data signal comprises an audio data signal and wherein the scalar defines a coarseness of the degraded data signal.

33. A method as claimed in claim 30, wherein the acquired data signal comprises an image data signal and wherein the scalar defines a quantization level of the degraded data signal.

34. A non-transitory computer readable medium comprising program instructions that, when executed by an apparatus, cause the apparatus to perform at least the following:
degrading an acquired data signal, using a source coding module, to generate a degraded signal having a fidelity dependent on a first measure of available energy, wherein the acquired data signal is degraded based on a scalar dependent on said first measure of available energy; and
generating an output based on the degraded data signal, wherein the output is generated using an inference module that has parameters dependent on a second measure of available energy, wherein the inference module is configured to output degradable inferences dependent on the degraded signal received by the inference module from the source coding module.

35. A non-transitory computer readable medium comprising program instructions, that, when executed by an apparatus, cause the apparatus to perform at least the following:
training parameters of an inference module that forms part of a system comprising a source coding module and the inference module, wherein the source coding module is configured to degrade an acquired data signal to generate a degraded data signal, based on a scalar selected dependent on an available energy, and
training the inference module, for a particular available energy, together with the source coding module, such that the inference module is configured to output degradable inferences dependent on the degraded signal received by the inference module from the source coding module.

36. A system comprising:
at least one processor; and
at least one memory
storing instructions that, when executed by the at least one processor, cause the apparatus at least to;
train an inference module, for a particular available energy, together with a source coding module;
degrade an acquired data signal, using the source coding module, to generate a degraded signal having a fidelity dependent on a first measure of available energy, and
generate by using the inference module an output based on the degraded data signal.
